(19) United States
(12) Patent Application Publication
(10) Pub. No.: US 2016/0211308 A1
(43) Pub. Date: Jul. 21, 2016

(54) ORGANIC LIGHT EMITTING DIODE DISPLAY

(71) Applicant: SAMSUNG DISPLAY CO., LTD., Yongin-si (KR)

(72) Inventor: Dae-Won LEE, Seoul (KR)

(21) Appl. No.: 14/848,489

(22) Filed: Sep. 9, 2015

(30) Foreign Application Priority Data
Jan. 15, 2015 (KR) 10-2015-0007631

(51) Int. Cl. H01L 27/32

(52) U.S. Cl. CPC H01L 27/3248; H01L 27/3276

(57) ABSTRACT

An organic light emitting diode display includes a scan line, a data line, a switching transistor, a driving transistor, and an organic light emitting diode. The switching transistor is connected to the scan line and the data line. The driving transistor is connected to the switching transistor. The organic light emitting diode is connected to the driving transistor. A switching contact hole connects the switching source electrode of the switching transistor to the data line and overlaps an outline of the switching source electrode.

### CROSS-REFERENCE TO RELATED APPLICATION

Korean Patent Application No. 10-2015-0007631, filed on Jan. 15, 2015, and entitled, “Organic Light Emitting Diode Display,” is incorporated by reference herein in its entirety.

### BACKGROUND

1. Field

One or more embodiments relate to an organic light emitting diode display.

2. Description of the Related Art

In an organic light emitting diode display, each pixel includes an organic light emitting layer between two electrodes. Electrons injected from a cathode and holes injected from an anode bond in the organic light emitting layer to form excitons. Light is emitted when the excitons discharge energy.

Each pixel also includes a plurality of thin film transistors and at least one capacitor for driving light emission. The transistors may include a switching transistor and a driving transistor. The driving transistor is sensitive to a leakage current, and the switching transistor is sensitive to an on/off characteristic.

In order to form a high resolution display, the each pixel may have a reduced size. The reduced size may lower the amount of current for driving the pixel. As a result, the driving range of the driving transistor may be narrowed. Consequently, it may be difficult to control the size of the driving gate-source voltage of the driving transistor. As a result, the number of grayscale values of light to be emitted by the pixels and may be limited and thus display quality may be adversely affected.

### SUMMARY

In accordance with one or more embodiments, an organic light emitting diode display includes a substrate; a scan line on the substrate to transmit a scan signal; a data line and a driving voltage line crossing the scan line and to respectively transmit a data voltage and a driving voltage; a switching transistor connected to the scan line and the data line; a driving transistor connected to the switching transistor; and an organic light emitting diode connected to the driving transistor, wherein a switching contact hole connecting the switching source electrode of the switching transistor to the data line overlaps an outline of the switching source electrode.

The outline of the switching source electrode may traverse the switching contact hole. The display may include a compensation transistor to be turned on depending on a scan signal to compensate a threshold voltage of the driving transistor, the compensation transistor connected to a driving drain electrode of the driving transistor; a driving connector to connect a compensation drain electrode of the compensation transistor to a driving gate electrode of the driving transistor: and a driving contact hole connecting the driving connector and the driving gate electrode, the driving contact hole positioned at an inside area enclosed by the outline of the driving gate electrode.

The display may include a first insulating layer covering a semiconductor including a switching channel of the switching transistor and a driving channel of the driving transistor; a second insulating layer covering the scan line formed on the first insulating layer; and a third insulating layer on the second insulating layer, wherein the switching contact hole penetrates the first insulating layer, the second insulating layer, and the third insulating layer. The driving contact hole may penetrate the second insulating layer and the third insulating layer.

The switching source electrode may be of a same layer as the switching channel, and the data line and driving voltage line may be on the third insulating layer. The driving channel may be curved on a plane.

The display may include a storage capacitor including a first storage electrode on the first insulating layer and may overlap the driving channel; and a second storage electrode may be on the first storage electrode and may overlap the first storage electrode, wherein the first storage electrode is the driving gate electrode. The second storage electrode may be between the second insulating layer and third insulating layer.

A compensation contact hole may connect a compensation drain electrode of the compensation transistor to the driving connector, and the compensation contact hole may overlap an outline of the compensation drain electrode. The display may include a previous scan line substantially parallel to the scan line and transmitting a previous scan signal; an initialization voltage line to transmit an initialization voltage; an initialization transistor between the initialization voltage line and the driving gate electrode, the initialization transistor to be turned on depending on the previous scan signal and to transmit the initialization voltage to the driving gate electrode; and an initialization connector including a same layer as the data line and connected to the initialization voltage line, and the initialization contact hole connecting the initialization source electrode of the initialization transistor to the initialization connecting member, the initialization contact hole overlaps the outline of the initialization source electrode.

The display may include an emission control line substantially parallel to the scan line to transmit an emission control signal; and an operation control transistor between the driving voltage line and the driving source electrode of the driving transistor and to be turned on depending on the emission control signal to transmit the driving voltage to the driving transistor, and an operation control contact hole connecting the operation control source electrode of the operation control transistor to the driving voltage line, the operation control contact hole overlapping the outline of the operation control source electrode.

The display may include an emission control transistor between the driving drain electrode of the driving transistor and the organic light emitting diode and to be turned on depending on the emission control signal to transmit the driving voltage to the organic light emitting diode; and an emission control connector including a same layer as the data line, wherein the emission control contact hole connects the emission control drain electrode of the emission control transistor to the emission control connecting member and wherein the emission control contact hole overlaps the outline of the emission control drain electrode.

The substrate may include a pixel are to display an image and a peripheral area, a plurality of peripheral transistors in the peripheral area and a plurality of peripheral signal lines to supply a peripheral signal to the peripheral transistors, and the driving transistor and the switching transistor are in the pixel area.

The peripheral transistor may include a peripheral channel, a peripheral source electrode, and a peripheral drain electrode on the substrate; and a peripheral gate electrode overlapping the peripheral channel, the peripheral source electrode is connected to a first peripheral signal line and the peripheral drain electrode is connected to a second peripheral signal line, and a peripheral source contact hole connects the peripheral source electrode and the first peripheral signal line and overlaps the outline of the peripheral source electrode. A peripheral drain contact hole may connect the peripheral drain electrode to the second peripheral signal line and overlaps the outline of the peripheral drain electrode.

### BRIEF DESCRIPTION OF THE DRAWINGS

Features will become apparent to those of skill in the art by describing in detail exemplary embodiments with reference to the attached drawings in which:

FIG. 1 illustrates an embodiment of an organic light emitting diode display;

FIG. 2 illustrates an embodiment of a pixel;

FIG. 3 illustrates an example of control signals for the pixel;

FIG. 4 illustrates an example of a layout view of the pixel;

FIG. 5 illustrates a more detailed layout view of the pixel;

FIG. 6 illustrates a view along section line VI-VI in FIG. 5;

FIG. 7 illustrates a view along section line VII-VII in FIG. 5;

FIG. 8 illustrates examples of driving current curves;

FIG. 9 illustrates an embodiment including a peripheral switching transistor of an organic light emitting diode display; and

FIG. 10 illustrates a view along section line X-X in FIG. 9.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. The embodiments may be combined to form additional embodiments.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the accompanying drawings, an active matrix (AM) type of organic light emitting diode (OLED) display is illustrated to have a 7Tr-1Cap structure, in which seven transistors (TFTs) and one capacitor are provided for one pixel. In another embodiment, each pixel may include a different number of transistors and/or capacitors, e.g., at least one capacitor. Additional wires may be added or one or more wires may be omitted in these other embodiments. A pixel may be considered to be a minimum unit for emitting light for an image, and the organic light emitting diode display displays images based on light from a plurality of pixels.

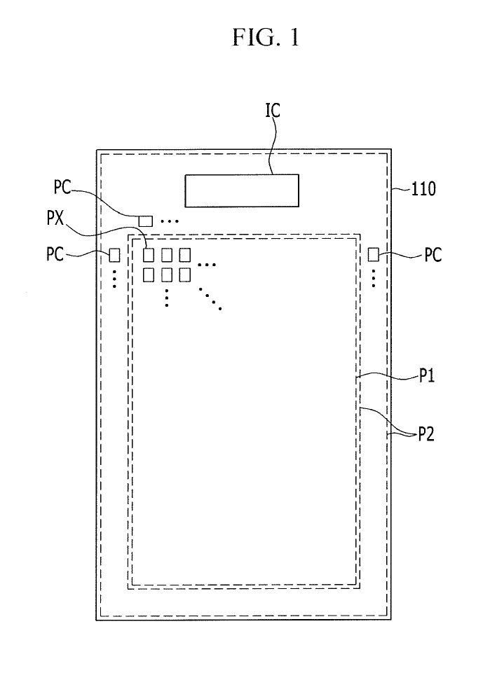

FIG. 1 illustrates an embodiment of an organic light emitting diode display which includes a pixel area P1 and a peripheral area P2 on a substrate 110. The pixel area P1 includes a plurality of unit pixels, each including an organic light emitting diode OLD for emitting light of an image. The peripheral area P2 surrounds the pixel area P1 and includes a plurality of peripheral circuits PC and at least one driving circuit chip IC.

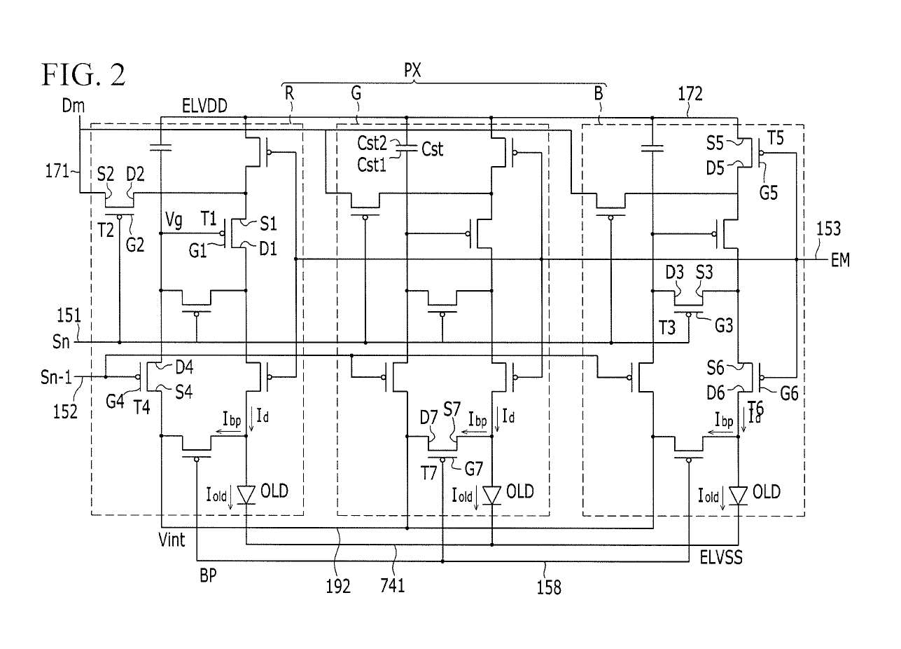

FIG. 2 illustrates an embodiment of the pixel area P1 which includes a plurality of signal lines and a plurality of unit pixels PX arranged in a matrix and connected to the signal lines. Each unit pixel PX may include a red pixel R, a green pixel G, and a blue pixel B. Each of the R, G, and B pixels may include a plurality of transistors, a storage capacitor Cst, and an organic light emitting diode OLD connected to the signal lines.

The transistors include a driving transistor T1, a switching transistor T2, a compensation transistor T3, an initialization transistor T4, an operation control transistor T5, a light emission control transistor T6, and a bypass transistor T7.

The signal lines include a scan line 151 for transferring a scan signal Sn, a previous scan line 152 for transferring a previous scan signal Sn-1 to the initialization transistor T4, a light emission control line 153 for transferring a light emission control signal EM to the operation control transistor T5 and the light emission control transistor 16, a bypass control line 158 for transferring a bypass signal BP to the bypass transistor T7, a data line 171 crossing the scan line 151 and for transferring a data signal Dm, a driving voltage line 172 for transferring a driving voltage ELVDD and substantially parallel to the data line 171, and an initialization voltage line 192 for transferring an initialization voltage Vint initializing the driving transistor T1.

The driving transistor T1 has a gate electrode G1 connected to one end Cst 1 of the storage capacitor Cst, a source electrode Si connected with the driving voltage line 172 via the operation control transistor T5, and a drain electrode D1 connected to an anode of the organic light emitting diode OLD via the light emission control transistor T6. The driving transistor T1 receives the data signal Dm according to a switching operation of the switching transistor T2 and supplies a driving current Id to the organic light emitting diode OLD.

The switching transistor T2 has a gate electrode G2 connected to the scan line 151, a source electrode S2 connected to the data line 171, and a drain electrode D2 connected to the source electrode S1 of the driving transistor T1 and with the driving voltage line 172 via the operation control transistor T5. The switching transistor T2 is turned on according to the scan signal Sn received through the scan line 151 and performs a switching operation for transferring the data signal Dm from the data line 171 to the source electrode of the driving transistor T1.

The compensation transistor T3 has a gate electrode G3 connected to the scan line 151, a source electrode S3 connected to the drain electrode D1 of the driving transistor T1 and an anode of the organic light emitting diode OLD via the emission control transistor T6, and a drain electrode D3 connected to one end Cst1 of the storage capacitor Cst and the drain electrode D4 of the initialization transistor T4, and the gate electrode G1 of the driving transistor T1. The compensation transistor T3 is turned on according to the scan signal Sn received through the scan line 151, to connect the gate electrode G1 and the drain electrode D1 of the driving transistor T1 and diode-connect the driving transistor T1.

The initialization transistor T4 has a gate electrode G4 connected to the previous scan line 152, a source electrode S4 connected to the initialization voltage line 192, and a drain electrode D4 connected to one end Cst1 of the storage capacitor Cst and the gate electrode G1 of the driving transistor T1 through the drain electrode D3 of the compensation transistor T3. The initialization transistor T4 is turned on according to a previous scan signal Sn-1 from the previous scan line 152 to transfer the initialization voltage Vint to the gate electrode G1 of the driving transistor T1, in order to initialize the voltage of the gate electrode G1 of the driving transistor T1.

The operation control transistor T5 has a gate electrode G5 connected to the light emission control line 153, a source electrode S5 connected to the driving voltage line 172, and a drain electrode D5 connected to the source electrode Si of the driving transistor T1 and the drain electrode S2 of the switching transistor 12.

The emission control transistor T6 has a gate electrode G6 connected to the light emission control line 153, the source electrode S6 connected to the drain electrode D1 of the driving transistor T1 and the source electrode S3 of the compensation transistor T3 and the drain electrode D6 connected to the anode of the organic light emitting diode OLD. The operation control transistor 15 and the first emission control transistor T6 are simultaneously turned on according to the emission control signal EM from the light emission control line 153, such that the driving voltage ELVDD is compensated through the diode-connected driving transistor T1 and is transmitted to the organic light emitting diode OLD.

The thin film bypass transistor T7 has a gate electrode G7 connected to the bypass control line 158, a source electrode S7 connected to the drain electrode D6 of the light emission control thin film transistor T6 and the anode of the organic light emitting diode OLED, and a drain electrode D7 connected to the initialization voltage line 192 and the source electrode S4 of the initialization thin film transistor T4.

The other end Cst2 of the storage capacitor Cst is connected to the driving voltage line 172, and a cathode of the organic light emitting diode OLED is connected to a common voltage line 741 for transferring a common voltage ELVSS.

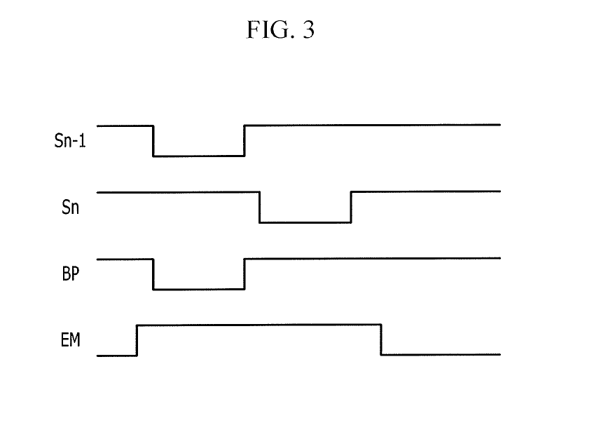

FIG. 3 is a timing diagram illustrating an example of pixel control signals. In an initializing period, the previous scan signal S(n-1) having a low level is supplied through the previous scan line 152. Then, the initializing thin film transistor T4 is turned on based on the previous scan signal S(n-1) having the low level, the initial voltage Vint is connected to the gate electrode G1 of the driving transistor T1 from the initialization voltage line 194 through the initializing thin film transistor T4, and then the driving thin film transistor TI is initialized by the initialization voltage Vint.

In a subsequent data programming period, the scan signal Sn having a low level is supplied through the scan line 151. Then, the switching thin film transistor T2 and the compensating thin film transistor 13 are turned on based on the scan signal Sn having the low level. At this time, the driving transistor T1 is diode-connected through the turned-on compensation transistor T3 and is biased in a forward direction.

Then, a compensation voltage Dm+Vth (Vth is a negative (−) value), which is reduced by a threshold voltage Vth of the driving thin film transistor T1 from a data signal Dm from the data line 171, is applied to the gate electrode G1 of the driving thin film transistor T1. Thus, the gate voltage Vg applied to the gate electrode G1 of the driving transistor T1 becomes the compensation voltage (Dm+Vth).

The driving voltage ELVDD and the compensation voltage (Dm+Vth) are applied to respective terminals of the storage capacitor Cst, and a charge corresponding to a voltage difference between the terminals is stored in the storage capacitor Cst.

In a subsequent emission period, the emission control signal EM from the emission control line 153 is changed from the high level into the low level. Thus, the operation control transistor T5 and the emission control transistor T6 are turned on by the emission control signal EM of the low level during the emission period.

Therefore, a driving current Id is generated according to the voltage difference between the gate voltage of the gate electrode G1 of the driving transistor T1 and the driving voltage ELVDD. The driving current Id is supplied to the organic light emitting diode OLD through the emission control transistor T6. The gate-source voltage Vgs of the driving thin film transistor T1 is maintained as “(Dm+Vth)-ELVDD” by the storage capacitor Cst for the emission period. According to a current-voltage relationship of the driving thin film transistor T1, the driving current Id is proportional to the square “(Dm−ELVDD)2” of a value which is obtained by subtracting the threshold voltage from the source-gate voltage. Accordingly, the driving current Id is determined regardless of the threshold voltage Vth of the driving thin film transistor T1.

In this case, the bypass transistor T7 is controlled based on the bypass signal BP from the bypass control line 158. The bypass signal BP is a voltage of a predetermined level that may always turn off the bypass transistor T7 in this period. The bypass transistor T7 receives the voltage of the off level of the transistor through the gate electrode G7, such that the bypass transistor T7 is always in the off state in this period and the portion of the driving current Id is discharged as the bypass current Ibp through the bypass transistor T7 in the off state.

When a minimum current of the driving transistor T1 for displaying a black image flows as the driving current, the black image may not be normally displayed if the organic light emitting diode (OLED) is also emitting. Accordingly, in accordance with one embodiment, the bypass transistor T7 of the organic light emitting diode display may disperse a portion of the minimum current of the driving transistor T1 as the bypass current Ibp through the other current path, beside the current path of the organic light emitting diode side. The minimum current of the driving transistor T1 may correspond to the current for a condition where the driving transistor T1 is turned off, since the gate-source voltage Vgs of the driving transistor T1 is smaller than the threshold voltage Vth.

The minimum driving current (for example, a current of 10 pA or less) under the condition in which the driving transistor T1 is turned off is transferred to the organic light emitting diode OLD to be expressed as an image with black luminance. When the minimum driving current expressing a black image flows, influence on a bypass transfer of the bypass current Ibp is large. But, when a large driving current expressing an image such as a normal image or a white image flows, there may be little influence on the bypass current Ibp.

Accordingly, when the driving current displaying a black image flows, the light emission current Ioled of the organic light emitting diode OLED, which is reduced by the current amount of the bypass current Ibp which flows out from the driving current Id through the bypass transistor T7, has a minimum current amount corresponding to a level which may exactly express the black image. Therefore, a black luminance image is exactly implemented using the bypass transistor T7, thereby improving contrast ratio. The bypass signal BP may be the next scan signal S(n+1) or another signal.

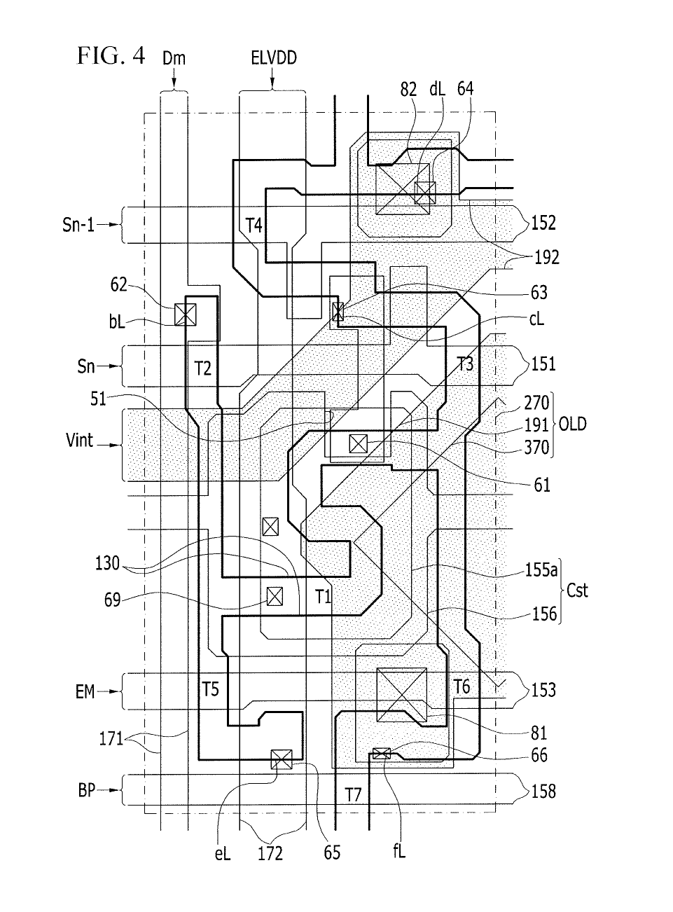

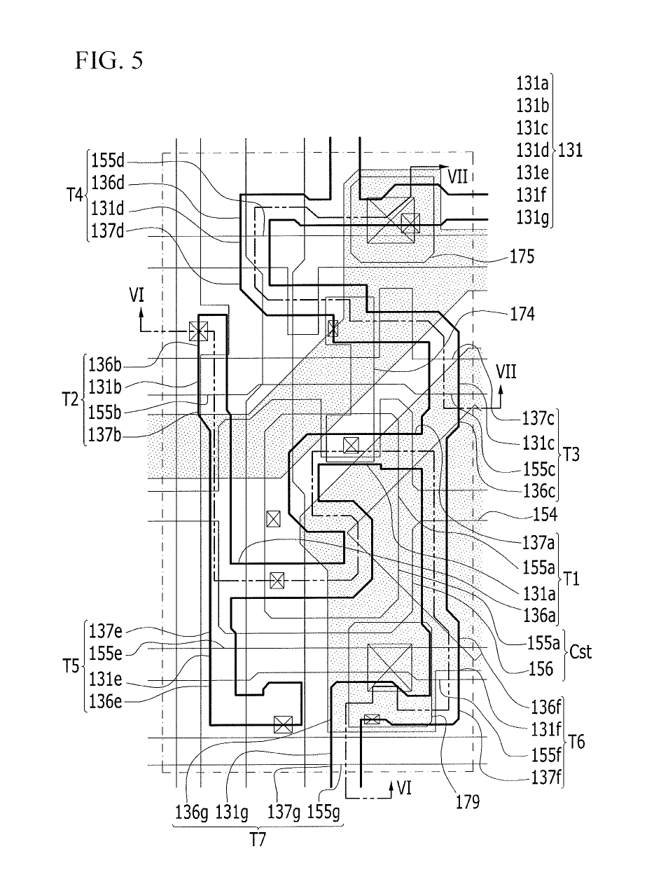

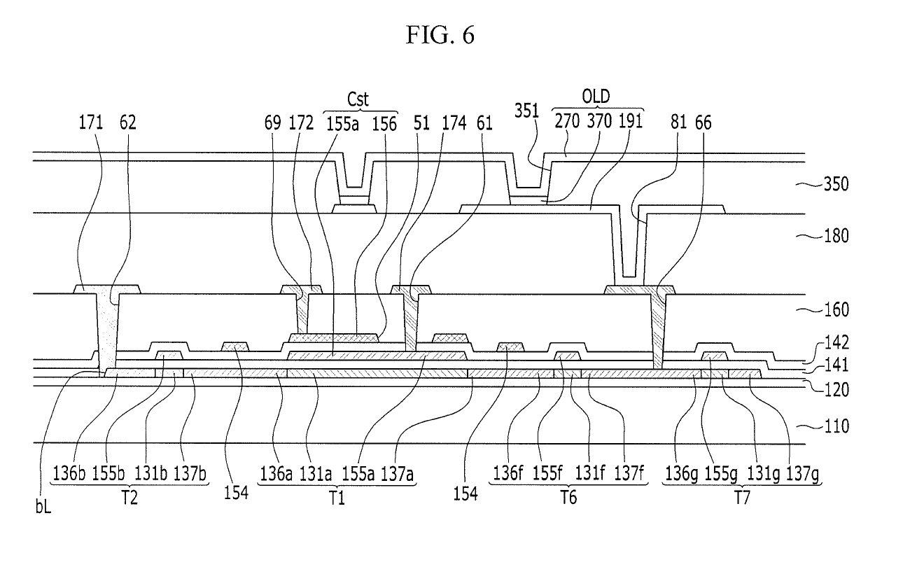

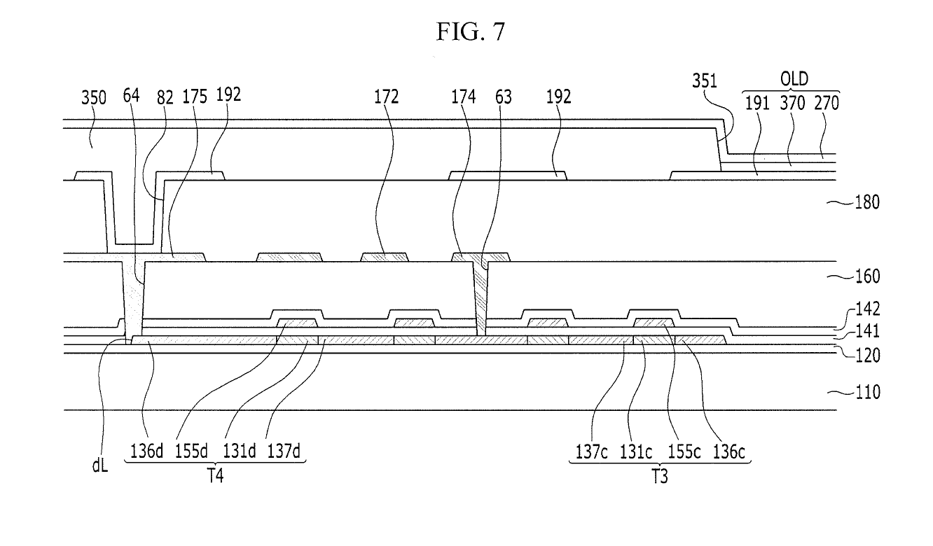

FIG. 4 illustrates an embodiment of a pixel which may be in a unit pixel PX in pixel area P1 in FIG. 2. FIG. 5 is a detailed layout (e.g., planar) view of FIG. 4, FIG. 6 is a cross-sectional view of the organic light emitting diode display of FIG. 5 taken along a line VI-VI, and FIG. 7 is a cross-sectional view of the organic light emitting diode display of FIG. 5 taken along a line VII-VII.

In FIG. 4, the pixel area P1 includes a scan line 151, a previous scan line 152, an emission control line 153, and a bypass control line 158 respectively transmitting a scan signal Sn, a previous scan signal Sn-1, an emission control signal EM, and a bypass signal BP to the pixel formed in a row direction. A data line 171 and a driving voltage line 172 cross the scan line 151, the previous scan line 152, the emission control line 153, and the bypass control line 158 and respectively apply a data signal Dm and a driving voltage ELVDD to the pixel. In this case, the initialization voltage line 192 for transmitting the initialization voltage Vint is formed bends multiple times along the row direction. The initialization voltage Vint is transmitted from the initialization voltage line 192 through the initialization transistor T4 to compensation transistor T3.

The pixel includes the driving thin film transistor T1, the switching thin film transistor T2, the compensation thin film transistor T3, the initialization thin film transistor T4, the operation control thin film transistor T5, the emission control thin film transistor T6, the bypass thin film transistor T7, the storage capacitor Cst, and the organic light emitting diode OLD. The organic light emitting diode OLD includes the pixel electrode 191, the organic emission layer 370, and the common electrode 270. The compensation transistor T3 and the initialization transistor T4 may be dual gate structure transistors in order to block leakage current.

Channels of the driving transistor T1, the switching transistor T2, the compensation transistor T3, the initialization transistor T4, the operation control transistor T5, the light emission control transistor T6, and the bypass transistor T7 are formed in one semiconductor 130. The semiconductor 130 may curve or meander in various shapes. The semiconductor 130 may include a polycrystalline semiconductor material or an oxide semiconductor material. Examples of the oxide semiconductor material include titanium (Ti), hafnium (Hf), zirconium (Zr), aluminum (Al), tantalum (Ta), germanium (Ge), zinc (Zn), gallium (Ga), tin (Sn), or indium (In), and indium-gallium-zinc oxide (InGaZnO4), indium-zinc oxide (Zn—In—O), zinc tin oxide (Zn—Sn—O), indium-gallium oxide (In—Ga—O), indium-tin oxide (In—Sn—O), indium-zirconium oxide (In—Zr—O), indium-zirconium-zinc oxide (In—Zr—Zn—O), indium-zirconium-tin oxide (In—Zr—Sn—O), indium-zirconium-gallium oxide (In—Zr—Ga—O), indium aluminum oxide (In—Al—O), indium-zinc-aluminum oxide (In—Zn—Al—O), indium-tin-aluminum oxide (In—Sn—Al—O), indium-aluminum-gallium oxide (In—Al—Ga—O), indium-tantalum oxide (In—Ta—O), indium-tantalum-zinc oxide (In—Ta—Zn—O), indium-tantalum-tin oxide (In—Ta—Sn—O), indium-tantalum-gallium oxide (In—Ta—Ga—O), indium-germanium oxide (In—Ge—O), indium-germanium-zinc oxide (In—Ge—Zn—O), indium-germanium-tin oxide (In—Ge—Sn—O), indium-germanium-gallium oxide (In—Ge—Ga—O), titanium-indium-zinc oxide (Ti—In—Zn—O), or hafnium-indium-zinc oxide (Hf—In—Zn—O) which is a compound oxide thereof. In the case where the semiconductor 130 is made of the oxide semiconductor material, a separate passivation layer for protecting the oxide semiconductor material which is vulnerable to an external environment such as a high temperature may be added.

The semiconductor 130 includes a channel 131 doped with an N-type impurity or a P-type impurity, and a source doping region and a drain doping region at respective sides of the channel and doped with an opposite-type doping impurity to the doping impurity of the channel. In one exemplary embodiment, the source doping region and the drain doping region correspond to the source electrode and the drain electrode, respectively. The source electrode and the drain electrode formed in the semiconductor 130 may be formed by doping only the corresponding regions. Further, in the semiconductor 130, a region between source electrodes and drain electrodes of different transistors is doped, and thus the source electrode and the drain electrode may be electrically connected to each other.

In FIG. 4, the channel 131 includes a driving channel 131a formed in the drive transistor T1, a switching channel 131b formed in the switching transistor T2, a compensation channel 131c formed in the compensation transistor T3, an initialization channel 131d formed in the initialization transistor T4, an operation control channel 131e formed in the operation control transistor T5, a light emission control channel 131f formed in the light emission control transistor T6, and a bypass channel 131g formed in the bypass transistor T7.

The driving transistor T1 includes the driving channel 131a, a driving gate electrode 155a, a driving source electrode 136a, and a driving drain electrode 137a. The driving channel 131a is curved and may have a predetermined shape, e.g., oblique, meandering, or zigzag shape. As such, by forming the curved driving channel 131a, the driving channel 131a may be formed to be elongated in a narrow space. The driving range of the driving gate-source voltage Vgs between the driving gate electrode 155a and the driving source electrode 136a is increased by the elongated driving channel 131a.

The driving range of the driving gate-source voltage Vgs may correspond to a difference between the maximum driving gate-source voltage of the driving transistor for the maximum grayscale value and the minimum driving gate-source voltage of the driving transistor for the minimum grayscale value, or may correspond to the difference between the driving gate-source voltages Vgs for each value or step of a grayscale range.

Since the driving range of the gate voltage is increased, a grayscale of light emitted from the organic light emitting diode OLD may be finely controlled by changing the magnitude of the gate voltage. As a result the resolution of the organic light emitting diode display device may be enhanced and display quality may be improved. The shape of the driving channel 131a may have various shapes, e.g., ‘reverse S’, ‘S’, ‘M’, and ‘W.’

The driving gate electrode 155a overlaps the driving channel 131a. The driving source electrode 136a and the driving drain electrode 137a are formed at respective sides of the driving channel 131a to be close. The driving source electrode 136a and the driving drain electrode 137a are positioned in the semiconductor 130 like the driving channel 131a. The driving gate electrode 155a is connected to a driving connecting member 174 through a contact hole 61.

In this case, the driving contact hole 61 is positioned inside and surrounded by an outline of the driving gate electrode 155a, such that the driving contact hole 61 is normally aligned with the driving gate electrode 155a. If the driving contact hole 61 is slightly moved so that it is not normally aligned with the driving gate electrode 155a (e.g., the driving contact hole 61 is formed at a position overlapping the outline of the driving gate electrode 155a), the driving range of the driving transistor T1 may decrease, thereby improving the charge mobility. However, when the driving contact hole 61 is normally aligned with the driving gate electrode 155a, such that the driving contact hole 61 is positioned at the inside enclosed by the driving gate electrode 155a, the driving range of the driving transistor is increased, thereby increasing the number of grayscale values that may be expressed by the pixel.

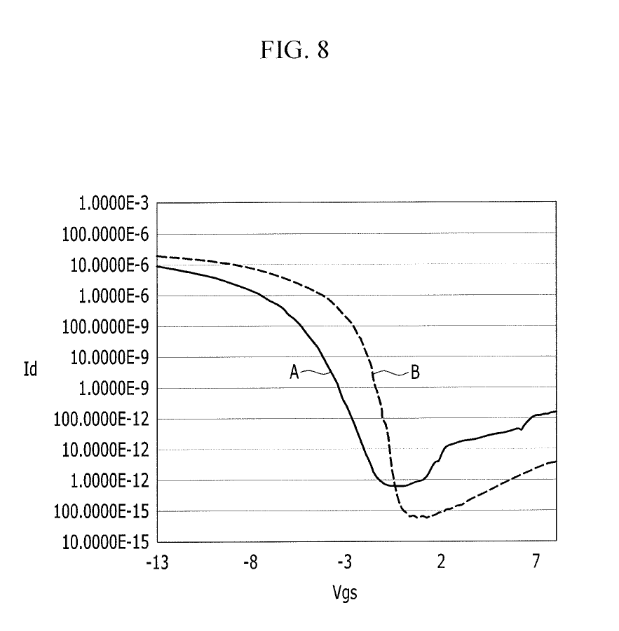

FIG. 8 is a graph illustrating two curves A and B. Curve A represents an example of the driving current of an organic light emitting diode display for at least one embodiment, and curve B represents an example of the driving current curve for another type of organic light emitting diode display.

More specifically, in FIG. 8, the x-axis represents the driving gate-source voltage Vgs applied between the driving gate electrode and the driving source electrode of the driving transistor, and the y-axis represents the driving current Id flowing to the organic light emitting diode Curve A indicates the driving current of the organic light emitting diode display where the driving contact hole is formed according to one or more embodiments disclosed herein. Curve B indicates the driving current curve of another the of organic light emitting diode display where alignment is shifted such that the driving contact hole is formed at a position overlapping the outline of the driving gate electrode.

In FIG. 8, since an inclination angle of the driving current curve A is lower than the driving current curve B of the shift-aligned organic light emitting diode display, the driving range of the driving gate-source voltage Vgs of the driving transistor of the organic light emitting diode display according to an exemplary embodiment is wider than the driving range of the driving gate-source voltage Vgs of the driving transistor of the shift-aligned organic light emitting diode display. This allows the present embodiment to control light emitted from the organic light emitting diode OLD in order to allow for expression of a greater number of grayscale values by differentiating the magnitude of the driving gate voltage Vg of the driving transistor T1.

As described above, the driving contact hole 61 of the pixel area P1 is normally aligned to be positioned inside and enclosed by the outline of the driving gate electrode 155a such that the driving range of the driving transistor T1 of the pixel area P1 is widened. This allows for an increase in the number of grayscale values of light that may be expressed.

The switching transistor T2 includes the switching channel 131b, a switching gate electrode 155b, a switching source electrode 136b, and a switching drain electrode 137b. The switching gate electrode 155b extends downward from the scan line 121 and overlaps the switching channel 131b. The switching source electrode 136b and the switching drain electrode 137b are formed at respective sides of the switching channel 131b to be close. The switching source electrode 136b and the switching drain electrode 137b are positioned inside the semiconductor 130 like the switching channel 131b. The switching source electrode 136b is connected with the data line 171 through a contact hole 62.

In this case, the switching contact hole 62 overlaps the outline bL of the switching source electrode 136b. Thus, the outline bL of the switching source electrode 136b traverses the switching contact hole 62. Accordingly, the driving range of the switching transistor is reduced such that the charge mobility is improved.

As described above, the switching contact hole 62 formed at the switching transistor T2 overlaps the outline bL of the switching source electrode 136b formed inside the semiconductor 130, thereby improving the charge mobility of the switching transistor T2.

The compensation transistor T3 includes the compensation channel 131c, a compensation gate electrode 155c, a compensation source electrode 136c, and a compensation drain electrode 137c. Two compensation transistors T3 are formed in order to prevent the leakage current, and two compensation gate electrodes 155c may respectively be a portion of the scan line 151 and a protrusion extended upwardly from the scan line 151. The compensation gate electrode 155c overlaps the compensation channel 131c, and the compensation source electrode 136c and the compensation drain electrode 137c are respectively formed to be adjacent to both sides of the compensation channel 131c. The compensation source electrode 136c and the compensation drain electrode 137c are positioned inside the semiconductor 130 like the compensation channel 131c. The compensation drain electrode 137c is connected to the driving connecting member 174 through a compensation contact hole 63. In this case, the compensation contact hole 63 overlaps the outline cL of the compensation source electrode 136c. Thus, the outline cL of the compensation source electrode 136c traverses the compensation contact hole 63. Accordingly, the driving range of the compensation transistor T3 is reduced, thereby improving the charge mobility.

The initialization transistor T4 includes the initialization channel 131d, an initialization gate electrode 155d, an initialization source electrode 136d, and an initialization drain electrode 137d. Two initialization transistors T4 are formed in order to prevent the leakage current, and two initialization gate electrodes 155d may respectively be a portion of the previous scan line 152 and a protrusion extended downwardly from the previous scan line 152. The initialization gate electrode 155d overlaps the initialization channel 131d, and the initialization source electrode 136d and the initialization drain electrode 137d are respectively formed to be adjacent to both sides of the initialization channel 131d. The initialization source electrode 136d and the initialization drain electrode I 37d are positioned inside the semiconductor 130 like the initialization channel 131d. The initialization source electrode 136d is connected to the initialization connecting member 175 through an initialization contact hole 64, and the initialization drain electrode 137d is connected to the driving connecting member 174 through the initialization contact hole 64.

In this case, the initialization contact hole 64 overlaps the outline dL of the initialization source electrode 136d. Thus, the outline dL of the initialization source electrode 136d traverses the initialization contact hole 64. Accordingly, the driving range of the initialization transistor T4 is reduced, thereby improving charge mobility.

The operation control transistor T5 includes the operation control channel 131e, an operation control gate electrode 155e, an operation control source electrode 136e, and an operation control drain electrode 137e. The operation control gate electrode 155e is a area of the light emission control line 153 and overlaps the operation control channel 131e. The operation control source electrode 136e and the operation control drain electrode 137e are formed at respective sides of the operation control channel 131e to be close. The operation control source electrode 136e and the operation control drain electrode 137e are positioned inside the semiconductor 130 like the operation control channel 131e. The operation control source electrode 136e is connected with a area of the driving voltage line 172 through a contact hole 65.

In this case the operation control contact hole 65 overlaps the outline eL of the operation control source electrode 136e. Thus, the outline eL of the operation control source electrode 136e traverses the operation control contact hole 65. Accordingly, the driving range of the initialization transistor T5 is reduced, thereby improving charge mobility.

The light emission control transistor T6 includes the light emission control channel 131f, a light emission control gate electrode 155f, a light emission control source electrode 136f, and a light emission control drain electrode 137f. The light emission control gate electrode 155f which is a area of the light emission control line 153 overlaps with the light emission control channel 131f, and the emission control source electrode 136f and the emission control drain electrode 137f are formed at respective sides of the emission control channel 131f to be close. The emission control source electrode 136f and the emission control drain electrode 137f are positioned inside the semiconductor 130 like the emission control channel 131f. The light emission control drain electrode 137f is connected with an emission control connection member 179 through a contact hole 66.

In this case, the emission control contact hole 66 overlaps the outline IL of the emission control source electrode 136f. Thus, the outline fL of the emission control source electrode 136f traverses the emission control contact hole 66. Accordingly, the driving range of the emission control transistor T6 is reduced, thereby improving charge mobility.

The bypass transistor T7 includes the bypass channel 131g, a bypass gate electrode 155g a bypass source electrode 136g, and a bypass drain electrode 137g. The bypass gate electrode 155g is area of the bypass control line 158 and overlaps the bypass channel 131g. The bypass source electrode 136g and the bypass drain electrode 137g are formed at respective sides of the bypass channel 131g to be close. The bypass source electrode 136g and the bypass drain electrode 137g are positioned inside the semiconductor 130 like the bypass channel 131g. The bypass source electrode 136g is connected to the emission control connecting member 179 through the emission control contact hole 66. The bypass drain electrode 137g is connected directly to the initialization source electrode 136d.

The driving source electrode 136a of the driving transistor T1 is connected to the switching drain electrode 137b and the operation control drain electrode 137e. The driving drain electrode 137a is connected to the compensation source electrode 136c and the emission control source electrode 136f.

The storage capacitor Cst includes a second insulating layer 142 between the first storage electrode 155a and a second storage electrode 156. The first storage electrode 155a corresponds to the driving gate electrode 155a. The second storage electrode 156 extends from a storage line 154, occupies a larger area than the driving gate electrode 155a, and fully covers the driving gate electrode 155a. The second insulating layer 142 is a dielectric material, and a storage capacitance is determined based on charges stored in the storage capacitor Cst and a voltage between the two electrodes 155a and 156. As such, the driving gate electrode 155a is used as the first storage electrode 155a. As a result, it is possible to ensure a space in which the storage capacitor may be formed in a space narrowed by the driving channel 131a having a large area in the pixel.

The first storage electrode 155a is the driving gate electrode that is connected to one end of the driving connection member 174 through the driving contact hole 61 and a storage opening 51. The storage opening 51 is in the second storage electrode 156.

The driving connection member 174 is formed on the same layer as and is substantially parallel to the data line 171. The other end of the driving connection member 174 is connected to the compensation drain electrode 137c of the compensation transistor T3 and the initialization drain electrode 137d of the initialization transistor T4 through the compensation contact hole 63. Accordingly, the driving connecting member 174 connects the driving gate electrode 155a and the compensation drain electrode 137c of the compensation transistor T3 and the initialization drain electrode 137d of the initialization transistor T4.

The second storage electrode 156 is connected to the driving voltage line 172 through a storage contact hole 69.

Accordingly, the storage capacitor Cst has a storage capacitance based on a difference between the driving voltage ELVDD transferred to the second storage electrode 156 through the driving voltage line 172 and the driving gate voltage Vg of the driving gate electrode 155a.

FIGS. 6 and 7 illustrate cross-sectional structures of the organic light emitting diode display device. Here, the lamination structure of the operation control transistor T5 may be the same as that of the light emission control transistor T6.

In FIGS. 6 and 7, a buffer layer 120 is formed on a substrate 110. The substrate 110 may be an insulating substrate that includes, for example, glass, crystal ceramic, or plastic. The buffer layer 120 blocks impurities from the substrate 110 during a crystallization process for forming a polycrystalline semiconductor and thus serves to improve characteristics of the polycrystalline semiconductor. The buffer layer 120 also planarizes the substrate 110 to smooth stress of the semiconductor 130 formed on the buffer layer 120. The buffer layer 120 may include, for example, silicon nitride (SiNx) or a silicon oxide (SiOx).

The semiconductor 130 is formed on the buffer layer 120 and includes a driving channel 131a, a switching channel 131b, a compensation channel 131c, an initialization channel 131d, an operation control channel 131e, and a light emission control channel 131f. A driving source electrode 136a and a driving drain electrode 137a are formed on respective sides of the driving channel 131a in the semiconductor 130. A switching source electrode 136b and a switching drain electrode 137b are formed on respective sides of the switching channel 131b. The compensation source electrode 136c and the compensation drain electrode 137c are formed at respective sides of the compensation channel 131c. The initialization source electrode 136d and the initialization drain electrode 137d are formed at respective sides of the initialization channel 131d. The operation control source electrode 136e and the operation control drain electrode 137e are formed at respective sides of the operation control channel 131e. The emission control source electrode 136f and the emission control drain electrode 137f are formed at respective sides of the emission control channel 131f. The bypass source electrode 136g and the bypass drain electrode 137g are formed at respective sides of the bypass channel 131g.

A first gate insulating layer 141 covering the semiconductor 130 is formed on the semiconductor 130. Various lines are formed on the first gate insulating layer 141. These lines include the scan line 151 having a switching gate electrode 155b and the compensation gate electrode 155c, the previous scan line 152 having the initialization gate electrode 155d, the emission control line 153 having an operation control gate electrode 155e and the emission control gate electrode 155f, the bypass control line 158 having a bypass gate electrode 155g, and the driving gate electrode (a first storage electrode) 155a.

The first gate wire 151, 152, 153, 155a, and 158 may be formed as a multilayer including a metal layer of copper (Cu), a copper alloy, aluminum (Al), an aluminum alloy, molybdenum (Mo), and a molybdenum alloy.

The second gate insulating layer 142 covers the first gate wire 151, 152, 153, 155a, and 158, and the first gate insulating layer 141 is formed thereon. The first gate insulating layer 141 and the second gate insulating layer 142 may include, for example, silicon nitride (SiNx) or a silicon oxide (SiOx).

Various features may be formed on the second gate insulating layer 142. These features include a storage line 154 parallel to the scan line 151 and a second storage electrode 156 extending from the storage line 154 are formed.

An interlayer insulating layer 160 is formed on the second gate insulating layer 142 and the second gate wire 154 and 156. The interlayer insulating layer 160 has contact holes including a driving contact hole 61, a switching contact hole 62, a compensation contact hole 63, an initialization contact hole 64, an operation control contact hole 65, an emission control contact hole 66, and a storage contact hole 69. The interlayer insulating layer 160 include, for example, a silicon nitride (SiNx) or a silicon oxide (SiOx).

A number of data wires are formed on the interlayer insulating layer 160. The data wires include a data line 171, a driving voltage line 172, a driving connecting member 174, an initialization connecting member 175, and an emission control connecting member 179.

The data line 171 is connected to the switching source electrode 136b through the switching contact hole 62, formed to have the same boundary in the first gate insulating layer 141, the second gate insulating layer 142, and the interlayer insulating layer 160. One end of the driving connecting member 174 is connected to the first storage electrode 155a through the driving contact hole 61, formed to have the same boundary in the second gate insulating layer 142 and the interlayer insulating layer 160. The other end of the driving connecting member 174 is connected to the compensation drain electrode 137c and the initialization drain electrode 137d through the compensation contact hole 63, formed to have the same boundary in the first gate insulating layer 141, the second gate insulating layer 142, and the interlayer insulating layer 160.

The initialization connecting member 175 is connected to the initialization source electrode 136d through the initialization contact hole 64 in the first gate insulating layer 141, the second gate insulating layer 142, and the interlayer insulating layer 160. In addition, the emission control connecting member 179 is connected to the emission control drain electrode 137f through the emission control contact hole 66 in the first gate insulating layer 141, the second gate insulating layer 142, and the interlayer insulating layer 160.

In this case, the driving contact hole 61 is positioned inside enclosed by the outline of the driving gate electrode 155a. Also, the switching contact hole 62 overlaps the outline bL of the switching source electrode 136b, the compensation contact hole 63 overlaps the outline cL of the compensation source electrode 136c, the initialization contact hole 64 overlaps the outline dL of the initialization source electrode 136d, the operation control contact hole 65 overlaps the outline eL of the operation control source electrode 136e, and the emission control contact hole 66 overlaps the outline fL of the emission control source electrode 136f. Accordingly, the driving range of the driving transistor is increased to allow for a greater number of grayscale values to be expressed. Also, the charge mobility of the switching transistor, the compensation transistor, the compensation transistor, the operation control transistor, and the emission control transistor of the pixel area may be simultaneously improved

The data wires 171, 172, 175, and 179 may be formed as the multilayer which includes a metal layer of copper (Cu), a copper alloy, aluminum (Al), an aluminum alloy, molybdenum (Mo), and a molybdenum alloy. For example, data wires 171, 172, 175, and 179 include a triple layer of titanium/aluminum/titanium (Ti/Al/Ti). molybdenum/aluminum/molybdenum (Mo/Al/Mo), or molybdenum/copper/molybdenum (Mo/Cu/Mo).

A passivation layer 180 is formed to cover the data wires 171. 172, 175, and 179 and the interlayer insulating layer 160. The passivation layer 180 covers the data wires 171, 172, 174, and 179 for planarization, such that the pixel electrode 191 may be formed on the passivation layer 180 without a step. Also, the passivation layer 180 may have a greater thickness than the interlayer insulating layer 160, such that parasitic capacitance may be reduced or minimized between the data wires 171, 172, 175, and 179 and the pixel electrode 191. The passivation layer 180 may include, for example, an organic material such as a polyacryl-based resin an a polyimide-based resin, or a deposition layer of the organic material and an inorganic material.

The pixel electrode 191 and the initialization voltage line 192 are formed on the passivation layer 180. The emission control connecting member 179 is connected to the pixel electrode 191 through a pixel contact hole 81 in the passivation layer 180. The initialization connecting member 175 is connected to the initialization voltage line 192 through an initialization voltage line contact hole 82 in the passivation layer 180.

A pixel definition layer PDL 350 is formed on the passivation layer 180, the initialization voltage line 192, and the edge of the pixel electrode 191. The pixel definition layer 350 has a pixel opening 351 exposing the pixel electrode 191. The pixel definition layer 350 may include, for example, an organic material such as a polyacrylate resin and a polyimide resin or silica-series inorganic materials.

The organic emission layer 370 is formed on the pixel electrode 191 exposed by the pixel opening 351. A common electrode 270 is formed on the organic emission layer 370. The common electrode 270 is formed on the pixel defined layer 350 for the plurality of pixels. As such, an organic light emitting diode OLD is formed to include the pixel electrode 191, the organic emission layer 370, and the common electrode 270.

The pixel electrode 191 is an anode serving as a hole injection electrode and the common electrode 270 is a cathode serving as an electron injection electrode. In another embodiment, the pixel electrode 191 may be the cathode and the common electrode 270 may be the anode based. The anode and cathode may be determined, for example, based on a driving method of the organic light emitting diode display. When holes and electrons are injected into the organic emission layer 370 from the pixel electrode 191 and the common electrode 270, respectively, excitons are formed when injected holes and electrons combine. When the excitons fall from an excited state to a ground state, light is emitted.

The organic emission layer 370 may include, for example, a low-molecular organic material or a high-molecular organic material such as poly(3,4-ethylenedioxythiophene) (PEDOT). Further, the organic emission layer 370 may be formed with multiple layers including at least one of an emission layer, a hole injection layer (HIL), a hole transporting layer (HTL), an electron transporting layer (EFL), and an electron injection layer (EIL). When the organic emission layer 370 includes all of the layers, the hole injection layer is disposed on the pixel electrode 191 which is the positive electrode, and the hole transporting layer, the emission layer, the electron transporting layer, and the electron injection layer are sequentially laminated thereon.

The organic emission layer 370 may include a red organic emission layer to emit red light, a green organic emission layer to emit green light and a blue organic emission layer to emit blue light. The red organic emission layer, the green organic emission layer, and the blue organic emission layer are included in a red pixel, a green pixel, and a blue pixel, respectively, to implement color images.

Further, in the organic emission layer 370, all of the red organic emission layer, the green organic emission layer, and the blue organic emission layer may be laminated together on the red pixel, the green pixel, and the blue pixel. A red color filter, a green color filter, and a blue color filter may be formed for each pixel to implement color images. In another embodiment, a white organic emission layer to emit white light is formed on all of the red pixel, the green pixel, and the blue pixel, and the red color filter, the green color filter, and the blue color filter are formed for each pixel to implement the color images. When the color images are implemented using the white organic emission layer and the color filters, a deposition mask for depositing the red organic emission layer, the green organic emission layer, and the blue organic emission layer on individual pixels (e.g., the red pixel, the green pixel, and the blue pixel, respectively) may not be used.

In another embodiment, the white organic emission layer may be formed as one organic emission layer to emit white light by laminating a plurality of organic emission layers. As an example, the white organic emission layer may include a configuration that enables the white light to be emitted by combining at least one yellow organic emission layer and at least one blue organic emission layer, a configuration that enables the white light to be emitted by combining at least one cyan organic emission layer and at least one red organic emission layer, a configuration that enables the white light to be emitted by combining at least one magenta organic emission layer and at least one green organic emission layer, and the like.

An encapsulation member to protect the organic light emitting diode OLED may be formed on the common electrode 270. The encapsulation member may be sealed to the substrate 110 by a sealant and may be formed of various materials, e.g., glass, quartz, ceramic, plastic, or metal. In another embodiment, a thin film encapsulation layer may be formed on the common electrode 270 by depositing the inorganic layer and the organic layer with the usage of the sealant.

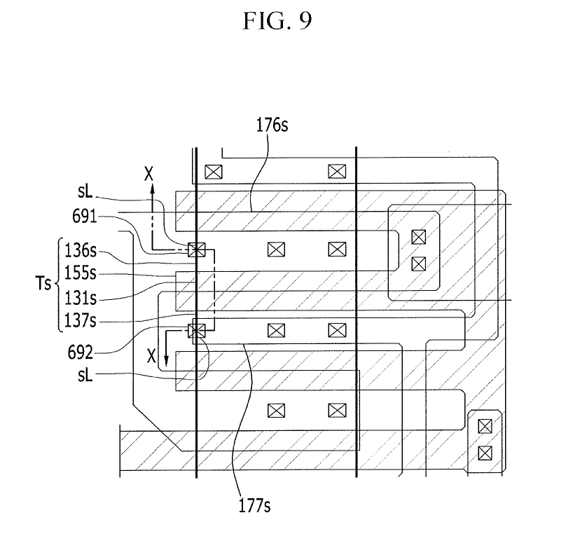

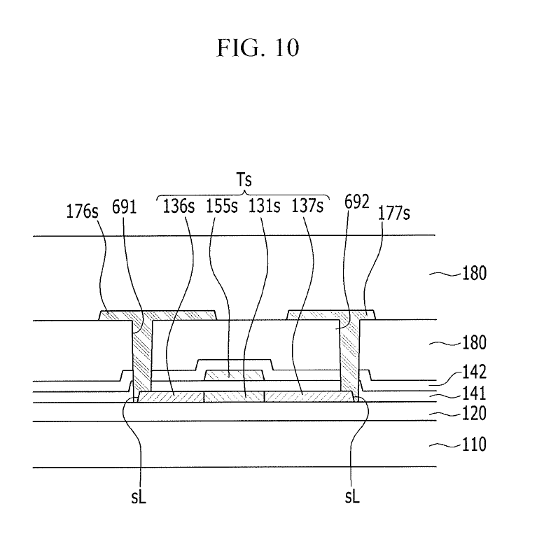

FIG. 9 illustrates an embodiment of a peripheral switching transistor in the peripheral area P2 the organic light emitting diode display in FIG. 1, and FIG. 10 illustrates a cross-sectional view taken along a line X-X in FIG. 9.

In FIGS. 9 and 10, a plurality of peripheral transistors Ts is formed in the peripheral circuit PC in the peripheral area P2. The peripheral transistor Ts may serve as a switching element to switch a peripheral circuit PC, e.g., a driving driver and a buffer in the peripheral area P2.

The peripheral transistor Ts includes a peripheral channel 131s, a peripheral gate electrode 155s, a peripheral source electrode 136s, and a peripheral drain electrode 137s. The peripheral gate electrode 155s overlaps the peripheral channel 131s. The peripheral source electrode 136s and the peripheral drain electrode 137s are formed to be adjacent to respective sides of the peripheral channel 131s. The peripheral source electrode 136s and the peripheral drain electrode 137s face each other on a plane relative to the peripheral gate electrode 155s. The peripheral source electrode 136s is connected to a first peripheral signal line 176s through a peripheral source contact hole 691. The peripheral drain electrode 137s is connected to a second peripheral signal line 177s through a peripheral drain contact hole 692.

In this case, the peripheral source contact hole 691 overlaps the outline sL of the peripheral source electrode 136s. The peripheral drain contact hole 692 overlaps the outline sL of the peripheral drain electrode 137s. Accordingly, the driving range of the peripheral transistor Ts is reduced such that charge mobility is improved.

The buffer layer 120 is formed also on the substrate 110 of the peripheral area P2. The peripheral channel 131s, the peripheral source electrode 136s, and the peripheral drain electrode 137s are formed on the buffer layer 120. The first gate insulating layer 141 is formed on and covers the peripheral channel 131s, the peripheral source electrode 136s, and the peripheral drain electrode 137. The peripheral gate electrode 155s is formed at a position overlapping the peripheral channel 131s on the first gate insulating layer 141. The second gate insulating layer 142 covering the peripheral gate electrode 155s is formed on the first gate insulating layer 141.

Also, the interlayer insulating layer 160 is formed on the second gate insulating layer 142. The first peripheral signal line 176s and the second peripheral signal line 177s are formed on the interlayer insulating layer 160. The first peripheral signal line 176s and the second peripheral signal line 177s are respectively connected to the peripheral source electrode 136s and the peripheral drain electrode 137s through the peripheral source contact hole 691 and the peripheral drain contact hole 692 in the first gate insulating layer 141, the second gate insulating layer 142, and the interlayer insulating layer 160.

The passivation layer 180 covering the first peripheral signal line 176s and the second peripheral signal line 177s is formed on the interlayer insulating layer 160.

By way of summation and review, the driving transistor in a pixel of an organic light emitting diode display may be sensitive to leakage current, and the switching transistor in the pixel and its surroundings may be sensitive to an on/off characteristic. Since a pixel may have a decreased size in a high resolution structure, the amount of current flowing for each pixel is reduced. As a result, the driving range of the driving transistor may be narrow. It may be difficult to control the size of the driving gate-source voltage applied to the driving transistor to express a sufficient number of grayscale values. Thus, display quality may be adversely affected.

In accordance with one or more of the aforementioned embodiments, by positioning a contact hole at the driving transistor of the pixel area inside an outline of the driving gate electrode, the driving range of the driving transistor may be increased to thereby allow for an greater number of grayscale values to be expressed. Additionally, by forming the contact hole at the switching transistor of the pixel area and the switching transistor of the peripheral area to overlap the outline of the semiconductor, the charge mobility of the switching transistor of the pixel area and the switching transistor of the peripheral area may be improved.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the invention as set forth in the following claims.

What is claimed is:

1. An organic light emitting diode display, comprising:
a substrate;
a scan line on the substrate to transmit a scan signal;
a data line and a driving voltage line crossing the scan line and to respectively transmit a data voltage and a driving voltage;
a switching transistor connected to the scan line and the data line;
a driving transistor connected to the switching transistor; and
an organic light emitting diode connected to the driving transistor, wherein a switching contact hole connecting a switching source electrode of the switching transistor to the data line overlaps an outline of the switching source electrode.

2. The display as claimed in claim 1, wherein the outline of the switching source electrode traverses the switching contact hole.

3. The display as claimed in claim 1, further comprising:
a compensation transistor to be turned on depending on a scan signal to compensate a threshold voltage of the driving transistor, the compensation transistor connected to a driving drain electrode of the driving transistor;
a driving connector to connect a compensation drain electrode of the compensation transistor to a driving gate electrode of the driving transistor; and
a driving contact hole connecting the driving connector and the driving gate electrode, the driving contact hole positioned at an inside area enclosed by the outline of the driving gate electrode.

4. The display as claimed in claim 3, further comprising:
a first insulating layer covering a semiconductor including a switching channel of the switching transistor and a driving channel of the driving transistor;
a second insulating layer covering the scan line formed on the first insulating layer; and
a third insulating layer on the second insulating layer, wherein the switching contact hole penetrates the first insulating layer, the second insulating layer, and the third insulating layer.

5. The display as claimed in claim 4, wherein the driving contact hole penetrate the second insulating layer and the third insulating layer.

6. The display as claimed in claim 4, wherein:
the switching source electrode is of a same layer as the switching channel, and
the data line and driving voltage line are on the third insulating layer.

7. The display as claimed in claim 4, wherein the driving channel is curved on a plane.

8. The display as claimed in claim 7, further comprising:
a storage capacitor including a first storage electrode on the first insulating layer and overlapping the driving channel; and
a second storage electrode on the first storage electrode and overlapping the first storage electrode, wherein the first storage electrode is the driving gate electrode.

9. The display as claimed in claim 8, wherein the second storage electrode is between the second insulating layer and the third insulating layer.

10. The display as claimed in claim 4, wherein:
a compensation contact hole connects a compensation drain electrode of the compensation transistor to the driving connector, and
the compensation contact hole overlaps an outline of the compensation drain electrode.

11. The display as claimed in claim 10, further comprising:
a previous scan line substantially parallel to the scan line and transmitting a previous scan signal;
an initialization voltage line to transmit an initialization voltage;
an initialization transistor between the initialization voltage line and the driving gate electrode, the initialization transistor to be turned on depending on the previous scan signal and to transmit the initialization voltage to the driving gate electrode; and
an initialization connector including a same layer as the data line and connected to the initialization voltage line, and
an initialization contact hole connecting an initialization source electrode of the initialization transistor to the initialization connector, the initialization contact hole overlaps the outline of the initialization source electrode.

12. The display as claimed in claim 11, further comprising:
an emission control line substantially parallel to the scan line to transmit an emission control signal; and
an operation control transistor between the driving voltage line and a driving source electrode of the driving transistor and to be turned on depending on the emission control signal to transmit the driving voltage to the driving transistor, and
an operation control contact hole connecting an operation control source electrode of the operation control transistor to the driving voltage line, the operation control contact hole overlapping the outline of the operation control source electrode.

13. The display as claimed in claim 12, further comprising:
an emission control transistor between the driving drain electrode of the driving transistor and the organic light emitting diode and to be turned on depending on the emission control signal to transmit the driving voltage to the organic light emitting diode: and
an emission control connector including a same layer as the data line, wherein an emission control contact hole connects an emission control drain electrode of the emission control transistor to the emission control connector, the emission control contact hole overlapping the outline of the emission control drain electrode.

14. The display as claimed in claim 4, wherein:
the substrate includes a pixel to display an image and a peripheral area,
a plurality of peripheral transistors in the peripheral area, and
a plurality of peripheral signal lines to supply a peripheral signal to the peripheral transistors, and
the driving transistor and the switching transistor are in the pixel area.

15. The display as claimed in claim 14, wherein:
the peripheral transistor includes a peripheral channel, a peripheral source electrode, and a peripheral drain electrode on the substrate; and a peripheral gate electrode overlapping the peripheral channel,
the peripheral source electrode is connected to a first peripheral signal line and the peripheral drain electrode is connected to a second peripheral signal line, and
a peripheral source contact hole connects the peripheral source electrode and the first peripheral signal line and overlaps the outline of the peripheral source electrode.

16. The display as claimed in claim 15, wherein a peripheral drain contact hole connects the peripheral drain electrode to the second peripheral signal line and overlaps the outline of the peripheral drain electrode.
